(19) United States
(12) Patent Application Publication
(10) Pub. No.: US 2026/0045905 A1
(43) Pub. Date: Feb. 12, 2026

(54) OSCILLATOR

(71) Applicant: Nihon Dempa Koygo Co., Ltd., Tokyo (JP)

(72) Inventor: Kotaro HAYASHI, Saitama (JP)

(73) Assignee: Nihon Dempa Koygo Co., Ltd., Tokyo (JP)

(21) Appl. No.: 19/329,886

(22) Filed: Sep. 16, 2025

Related U.S. Application Data
(63) Continuation of application No. PCT/JP2024/006069, filed on Feb. 20, 2024.

(30) Foreign Application Priority Data
Mar. 17, 2023 (JP) 2023-042841

(51) Int. Cl. H03B 5/04; H03B 5/32

(52) U.S. Cl. CPC H03B 5/04; H03B 5/32

(57) ABSTRACT

An oscillator capable of preventing a delay in correction of frequency temperature characteristics by measuring an ambient temperature before a temperature of a crystal vibration plate is changed and capable of reducing hysteresis of the frequency temperature characteristics.

A surface-mount type oscillator provided with an ambient temperature measuring sensor 15 that measures a temperature for correcting frequency temperature characteristics, on a substrate 1 on which a plurality of circuits are mounted, in which the ambient temperature measuring sensor 15 is disposed closer to a metal cover 2 than a reference crystal oscillator 11 including a crystal vibration plate and other circuits, and measures a temperature via a copper foil 16 for thermal conduction that is soldered to the metal cover 2 by the soldered portion 17, and the measured temperature is used for correcting the frequency temperature characteristics.

This is a Continuation of PCT/JP2024/006069 filed Feb. 20, 2024 and published in Japanese, which has a priority of Japanese no. 2023-042841 filed Mar. 17, 2023, hereby incorporated by reference.

### BACKGROUND OF THE INVENTION

### 1. Field of the Invention

The present invention relates to an oscillator, and particularly to an oscillator capable of preventing a delay in correction of frequency temperature characteristics by measuring an ambient temperature before a temperature of a crystal vibration plate changes.

### 2. Description of the Related Art

### Prior Art

In a conventional oscillator, a thermistor is disposed in the vicinity of a reference crystal oscillator including a crystal vibration plate for measuring a temperature of the reference crystal oscillator, and a frequency correction amount is calculated according to the measured temperature using a computation circuit (central processing unit (CPU)), and the frequency temperature characteristics are corrected by the frequency correction amount.

### Conventional Oscillator: FIG. 5, Instant Application.

A configuration of the conventional oscillator will be described with reference to FIG. 5. FIG. 5 consists of FIG. 5(A) and FIG. 5(B) and is an explanatory diagram of a side surface and a plane of the conventional oscillator. It should be noted that FIG. 5(A) is a side surface explanatory diagram, and FIG. 5(B) is a plane explanatory diagram.

As illustrated in FIG. 5, the conventional oscillator is a surface-mount type, and a metal cover 2 is fixed to a substrate 1 by soldering portions 17.

A plane of the substrate 1 of the conventional oscillator includes a thermistor 10, a reference crystal oscillator 11, a frequency-voltage controlled oscillator 12, a central processing unit (CPU) 13, a field programmable gate array (FPGA) 14, and soldering portions 17 formed at four corners of the plane of the substrate 1.

The thermistor 10 is disposed in the vicinity of the reference crystal oscillator 11 in order to measure the temperature of the reference crystal oscillator 11.

### Circuit Configuration of Conventional Oscillator: FIG. 6

A circuit configuration of the conventional oscillator will be described with reference to FIG. 6. FIG. 6 is a schematic diagram of the circuit configuration of the conventional oscillator.

In the circuit configuration of the conventional oscillator, as illustrated in FIG. 6, an oscillation frequency signal oscillated by the reference crystal oscillator 11 is input to the FPGA 14, the FPGA 14 outputs a control voltage to the frequency-voltage controlled oscillator 12, and the frequency-voltage controlled oscillator 12 outputs a specific frequency.

In addition, the thermistor 10 measures the temperature around the reference crystal oscillator 11, and the CPU 13 calculates a frequency correction value based on the measured temperature value and outputs the frequency correction value to the FPGA 14.

In the FPGA 14, the oscillation frequency from the reference crystal oscillator 11 is corrected by the frequency correction value input from the CPU 13.

It should be noted that the voltage corresponding to the measured temperature is output from the thermistor 10, and is converted from analog to digital (A/D conversion) in a case of being input to the CPU 13, is input to a frequency correction value calculation unit 13a, and the frequency correction value is calculated by the frequency correction value calculation unit 13a.

In addition, the FPGA 14 includes a digital direct synthesizer (DDS) 14a and a phase locked loop (PLL) 14b.

### Thermal Circuit Model of Conventional Oscillator: FIG. 7

A thermal circuit model of the conventional oscillator will be described with reference to FIG. 7. FIG. 7 is a schematic diagram of the thermal circuit model of the conventional oscillator. It should be noted that FIG. 7 is a schematic diagram illustrating a temperature change in the conventional oscillator by thermal resistance or thermal capacity.

As illustrated in FIG. 7, the thermal circuit model of the conventional oscillator has a configuration in which the reference crystal oscillator 11 and the thermistor 10 are connected in parallel to a+side of a power supply voltage V2. Here, the power supply voltage is obtained by replacing the ambient temperature with a voltage.

Each part is represented by thermal resistance (R) and thermal capacity (C).

In FIG. 7, “Ta” indicates the ambient temperature, “T_Xtal” indicates a temperature of the crystal vibration plate (reference crystal oscillator 11), and “T_Thermistor” indicates the measured temperature of the thermistor 10.

### Temperature Following Characteristics of Conventional Oscillator: FIG. 8

Temperature following characteristics of the conventional oscillator will be described with reference to FIG. 8. FIG. 8 is a graph illustrating the temperature following characteristics of the conventional oscillator. FIG. 8 is a graph in which the ambient temperature is increased until after 360 minutes and kept constant, and then decreased from 400 minutes.

As illustrated in FIG. 8, in the temperature following characteristics of the conventional oscillator, the temperature (T_Xtal) of the crystal vibration plate (reference crystal oscillator 11) rises and falls with a delay with respect to the rise and fall of the ambient temperature (Ta), whereas the temperature (T_Thermistor) of the thermistor 10 follows the temperature (T_Xtal) of the crystal vibration plate with a further delay in its rise and fall.

The frequency correction value calculation unit 13a calculates the frequency correction value using the temperature (T_Thermistor) of the thermistor 10 and provides the frequency correction value to the DDS 14a in the FPGA 14, so that the frequency temperature characteristics of the reference crystal oscillator 11 are corrected by the DDS 14a.

### Related Art

It should be noted that, as a related prior art, there is Japanese Patent Laid-Open Publication No. H01-208904A “Temperature Compensated Crystal Oscillator” (Patent Literature 1).

Patent Literature 1 discloses a configuration in which, in a temperature compensated crystal oscillator, the temperature change response time of a temperature measuring device that measures an ambient temperature is made equal to the temperature change response time of a crystal oscillation element.

### Prior Art Literature

### Patent Literature

[Patent Literature 1] Japanese Patent Laid-Open Publication No. H01-208904

However, in the conventional oscillator, since the temperature change of the crystal vibration plate inside the container cannot be promptly followed, and the frequency temperature characteristics are corrected by measuring the temperature with a delay, there is a problem that a delay in correction of the frequency temperature characteristics occurs, which causes hysteresis of the frequency temperature characteristics.

It should be noted that Patent Literature 1 improves the response characteristics of the temperature measuring device to the temperature change, but since it has a configuration that follows the measured temperature, a delay in frequency correction occurs.

Therefore, Patent Literature 1 does not disclose a configuration that prevents the delay in the correction of the frequency temperature characteristics and reduces the hysteresis of the frequency temperature characteristics.

### SUMMARY OF THE INVENTION

The present invention has been made in view of the above circumstances, and aims to provide an oscillator that is capable of preventing a delay in correction of frequency temperature characteristics by measuring an ambient temperature before a temperature of a crystal vibration plate is changed and that is capable of reducing hysteresis of the frequency temperature characteristics.

The present invention for solving the problem of the above-described conventional example provides a surface-mount type oscillator having a metal cover, the oscillator including: a temperature sensor disposed on a substrate, on which a plurality of circuits are mounted, at a position where a distance to the metal cover is shorter than a distance to the plurality of circuits and configured to measure a temperature via a copper foil for thermal conduction soldered to the metal cover in order to correct frequency temperature characteristics of a crystal vibration plate; a transient thermal response calculation unit configured to, with respect to a structural transient thermal response, calculate, as a crystal vibration plate estimated temperature (T_Xtal_est), a temperature value having a thermal conduction delay that becomes the same as a temperature (T_Xtal) of the crystal vibration plate which is obtained by simulation from a value (T_TaSensor) of the temperature measured by the temperature sensor, the value (T_TaSensor) having a smaller thermal conduction delay than the temperature (T_Xtal) of the crystal vibration plate when the crystal vibration plate receives thermal conduction of an ambient temperature (Ta), and configured to calculate a control value based on a crystal vibration plate estimated temperature (T_Xtal_est); and a frequency correction value calculation unit configured to compute a correction value of the frequency temperature characteristics based on the control value calculated from the crystal vibration plate estimated temperature, thereby producing an effect of preventing a delay in correction of the frequency temperature characteristics by measuring the ambient temperature before the crystal vibration plate and reducing hysteresis of the frequency temperature characteristics.

In the above oscillator of the present invention, the transient thermal response calculation unit includes a CR filter-type transient thermal model including parameters of a thermal resistance value and a thermal capacity value of the transient thermal response by simulation, and calculates the crystal vibration plate estimated temperature by using the transient thermal model.

In the above oscillator of the present invention, the copper foil for thermal conduction is soldered to the metal cover at corner portions at four corners of the substrate, and the temperature sensor is provided near the corner portion.

In the above oscillator of the present invention, the temperature sensor outputs the measured temperature to the transient thermal response calculation unit by a serial communication method of inter-integrated circuit communication.

### BRIEF DESCRIPTION OF THE DRAWINGS

FIG. 1 consists of FIG. 1(A) and FIG. 1(B) and is an explanatory diagram of a side surface and a plane of the present oscillator.

FIG. 2 is a schematic diagram of a circuit configuration of the present oscillator.

FIG. 3 is a schematic diagram of a thermal circuit model of the present oscillator.

FIG. 4 is a graph illustrating temperature following characteristics of the present oscillator.

FIG. 5 consists of FIG. 5(A) and FIG. 5(B) and is an explanatory diagram of a side surface and a plane of a conventional oscillator.

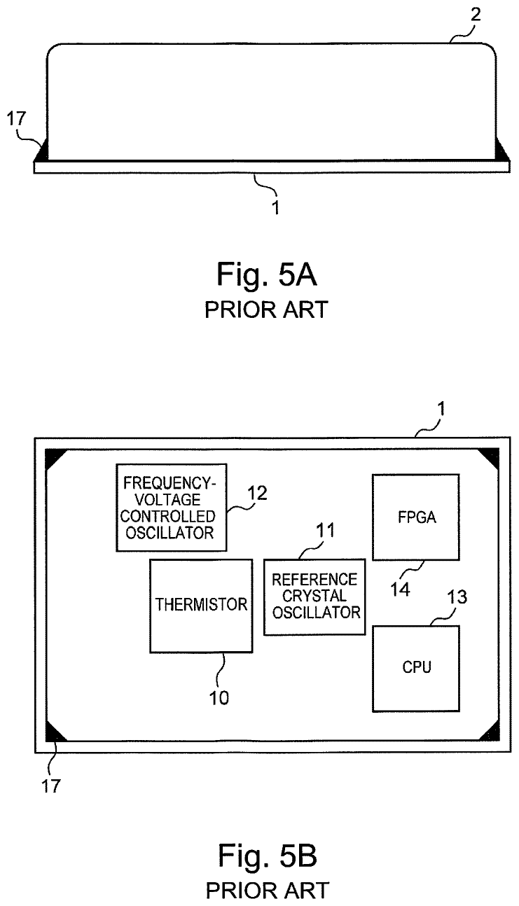

FIG. 6 is a schematic diagram of a circuit configuration of the conventional oscillator.

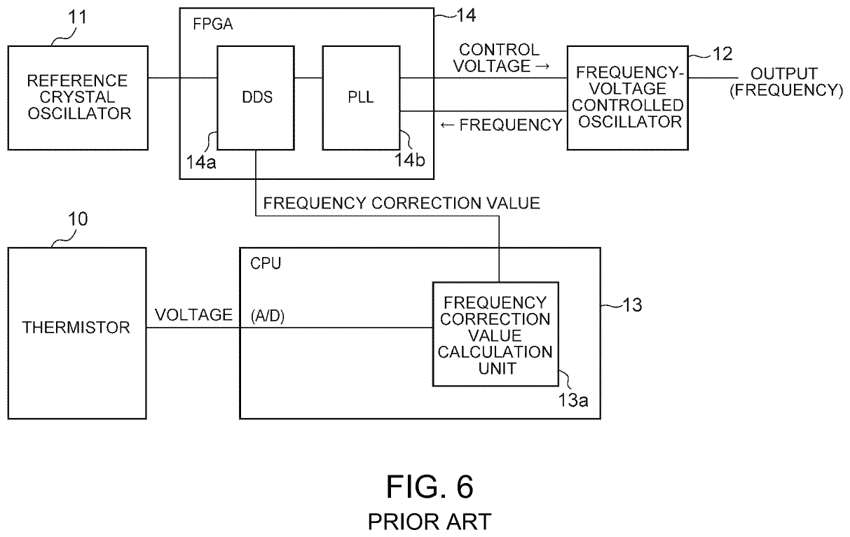

FIG. 7 is a schematic diagram of a thermal circuit model of the conventional oscillator.

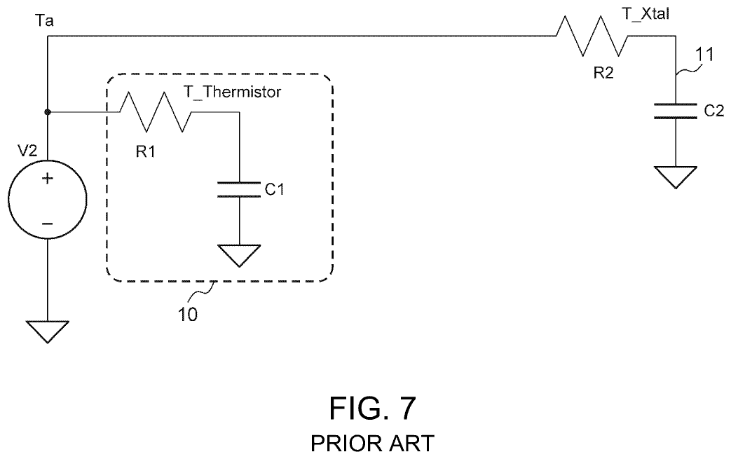

FIG. 8 is a graph illustrating temperature following characteristics of the conventional oscillator.

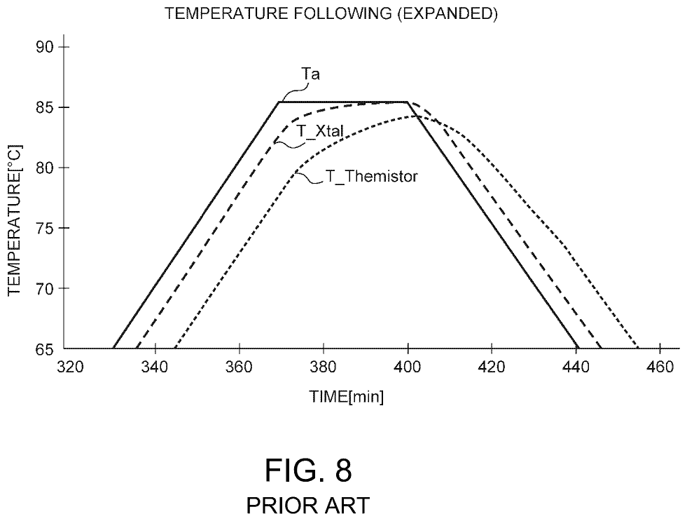

### DESCRIPTION OF REFERENCE NUMERALS

1: substrate, 2: metal cover, 10: thermistor, 11: reference crystal oscillator, 12: frequency-voltage controlled oscillator, 13: CPU (Central Processing Unit), 14: FPGA (Field Programmable Gate Array), 15: ambient temperature measuring sensor, 16: copper foil for thermal conduction, 17: soldered portion

### DESCRIPTION OF PREFERRED EMBODIMENT

An embodiment of the present invention will be described with reference to the drawings.

### Outline of Embodiment

An oscillator (the present oscillator) according to the embodiment of the present invention is a surface-mount type crystal oscillator having a metal cover, in which a temperature sensor that measures a temperature for correcting frequency temperature characteristics is provided on a substrate on which a plurality of circuits are mounted, the temperature sensor is disposed at a position where a distance to the metal cover is shorter than a distance to a reference crystal oscillator including a crystal vibration plate and other circuits, and measures a temperature via a copper foil for thermal conduction soldered to the metal cover, and the measured temperature is used for correcting the frequency temperature characteristics. The oscillator is capable of preventing a delay in correction of frequency temperature characteristics by measuring an ambient temperature before a temperature of the crystal vibration plate changes and is capable of reducing hysteresis of the frequency temperature characteristics.

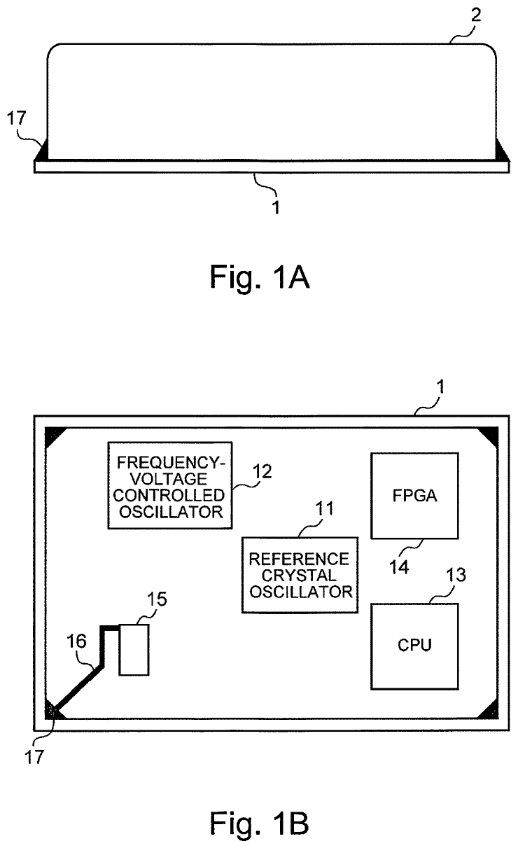

A configuration of the present oscillator will be described with reference to FIG. 1. FIG. 1 consists of FIG. 1(A) and FIG. 1(B) and is an explanatory diagram of a side surface and a plane of the present oscillator. It should be noted that FIG. 1(A) is a side surface explanatory diagram, and FIG. 1(B) is a plane explanatory diagram.

As illustrated in FIG. 1, the present oscillator is a surface-mount type, and a metal cover 2 is fixed to a substrate 1 by soldering portions 17.

A plane of a substrate 1 of the present oscillator includes a reference crystal oscillator 11, a frequency-voltage controlled oscillator 12, a central processing unit (CPU) 13, a field programmable gate array (FPGA) 14, an ambient temperature measuring sensor 15, soldering portions 17 formed at four corners of the plane of the substrate 1, and a copper foil 16 for thermal conduction that connects the ambient temperature measuring sensor 15 to the soldered portion 17.

It should be noted that each part of the present oscillator will be described later.

In addition, as illustrated in (B) of FIG. 1, the ambient temperature measuring sensor 15 is provided in vicinity of the soldered portion 17 at a corner portion, which is one of the four corners of the substrate 1, closer to the metal cover 2 than other circuits in order to measure the temperature of the metal cover 2, and is connected to the soldered portion 17 through the copper foil 16 for thermal conduction.

That is, the ambient temperature measuring sensor 15 is disposed at a position where the distance to the metal cover 2 is shorter than the distance to the other circuits, and measures the temperature of the metal cover 2 via the copper foil 16 for thermal conduction and the soldering portion 17.

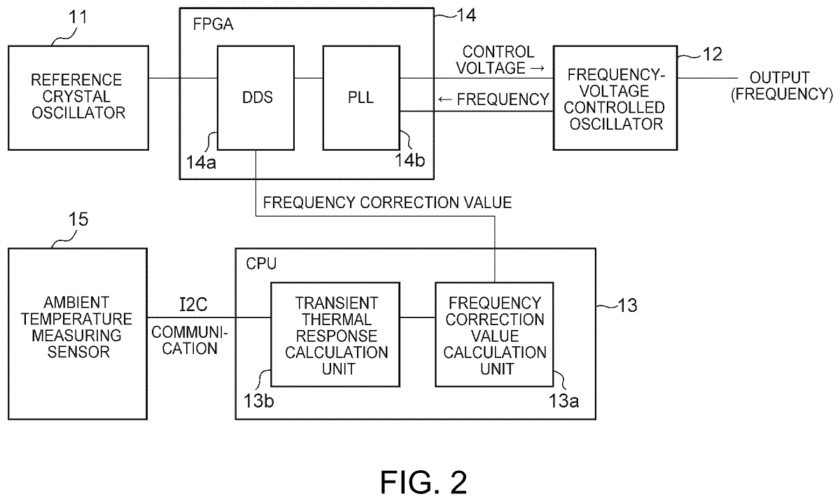

The circuit configuration of the present oscillator will be described with reference to FIG. 2. FIG. 2 is a schematic diagram of a circuit configuration of the present oscillator.

In the circuit configuration of the present oscillator, as illustrated in FIG. 2, an oscillation frequency signal oscillated by the reference crystal oscillator 11 is input to the FPGA 14, the FPGA 14 outputs a control voltage to the frequency-voltage controlled oscillator 12, and the frequency-voltage controlled oscillator 12 outputs a specific frequency.

In addition, the ambient temperature measuring sensor 15 measures the temperature of the metal cover 2, the CPU 13 calculates a temperature value of a thermal conduction delay due to the transient thermal response, and calculates a frequency correction value based on the temperature value to output the frequency correction value to the FPGA 14.

The “temperature value of thermal conduction delay” refers to a temperature value obtained that the reference crystal oscillator 11 obtains by receiving the thermal conduction from the surroundings with respect to the value of the temperature measured by the ambient temperature measuring sensor 15.

In the FPGA 14, the oscillation frequency from the reference crystal oscillator 11 is corrected by the frequency correction value input from the CPU 13.

Each part of the present oscillator will be specifically described.

The reference crystal oscillator 11 includes a crystal resonator and oscillates a reference frequency.

The reference crystal oscillator 11 has frequency temperature characteristics in which frequency characteristics change depending on the ambient temperature.

The frequency-voltage controlled oscillator 12 is a voltage controlled oscillator (VCO) that changes an oscillation frequency by a control voltage from the FPGA 14 and outputs the frequency.

The CPU 13 calculates a temperature value of thermal conduction delay due to the transient thermal response based on the temperature measured by the ambient temperature measuring sensor 15 and calculates the corresponding frequency correction value, and includes a frequency correction value calculation unit 13a and a transient thermal response calculation unit 13b.

The frequency correction value calculation unit 13a calculates a frequency correction value based on the temperature value input from the transient thermal response calculation unit 13b, and outputs the frequency correction value to a DDS 14a of the FPGA 14.

The transient thermal response calculation unit 13b includes a transient thermal computation model that calculates a temperature value of the thermal conduction delay for the transient thermal response. The transient thermal computation model includes parameters in a filter type as illustrated in a circuit of a schematic diagram described below. The transient thermal computation model is obtained in advance by actual measurement or thermal simulation.

The FPGA 14 is an integrated circuit in which a purchaser or a designer is capable of setting a configuration after manufacturing.

The digital direct synthesizer (DDS) 14a in the FPGA 14 is a device that freely modulates and outputs a frequency and a waveform, and corrects the reference frequency from the reference crystal oscillator 11 by the frequency correction value from the frequency correction value calculation unit 13a of the CPU 13.

In addition, a phase locked loop (PLL) 14b in the FPGA 14 synchronizes the phase of the input signal and the output signal by inputting a phase difference between an input signal of the reference frequency and a feedback signal of the output of the frequency-voltage controlled oscillator 12 of which the frequency changes according to the voltage, to the frequency-voltage controlled oscillator 12.

The ambient temperature measuring sensor 15 is a 16-bit high-accuracy temperature sensor IC, measures a temperature of the copper foil 16 for thermal conduction connected to the metal cover 2, and outputs information on the measured temperature to the CPU 13 by Inter-Integrated Circuit (I2C) communication that realizes high-speed communication in a serial communication method with the peripheral device.

In the copper foil 16 for thermal conduction, a copper foil having a high thermal conductivity is printed on the substrate 1, and the ambient temperature transmitted to the metal cover 2 is output to the ambient temperature measuring sensor 15 with a small error almost at the same time.

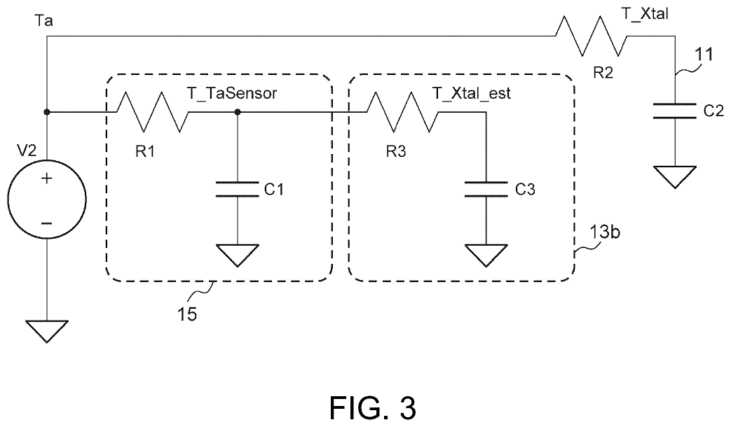

A thermal circuit model of the present oscillator will be described with reference to FIG. 3. FIG. 3 is a schematic diagram of the thermal circuit model of the present oscillator. It should be noted that FIG. 3 is a schematic diagram illustrating a temperature change in the present oscillator by thermal resistance or thermal capacity.

As illustrated in FIG. 3, in the thermal circuit model of the present oscillator, the reference crystal oscillator 11 and the ambient temperature measuring sensor 15 are connected in parallel to the + side of the power supply voltage V2, and the transient thermal response calculation unit 13b is connected to the ambient temperature measuring sensor 15.

Each part is represented by thermal resistance (R) and thermal capacity (C).

In FIG. 3, “Ta” indicates the ambient temperature, “T_Xtal” indicates a temperature of the crystal vibration plate (reference crystal oscillator 11), “T_TaSensor” indicates a temperature of the ambient temperature measuring sensor 15, and “T_Xtal_est” indicates a crystal vibration plate estimated temperature.

The crystal vibration plate estimated temperature is a temperature of the thermal conduction delay due to the transient thermal response, and corresponds to a temperature value calculated by the transient thermal response calculation unit 13b. Therefore, the transient thermal response calculation unit 13b holds parameters of the resistance (R3) and the capacity (C3) illustrated in the schematic circuit of FIG. 3 by simulation, and calculates a value of the crystal vibration plate estimated temperature (the temperature of the thermal conduction delay for the transient thermal response) by computation.

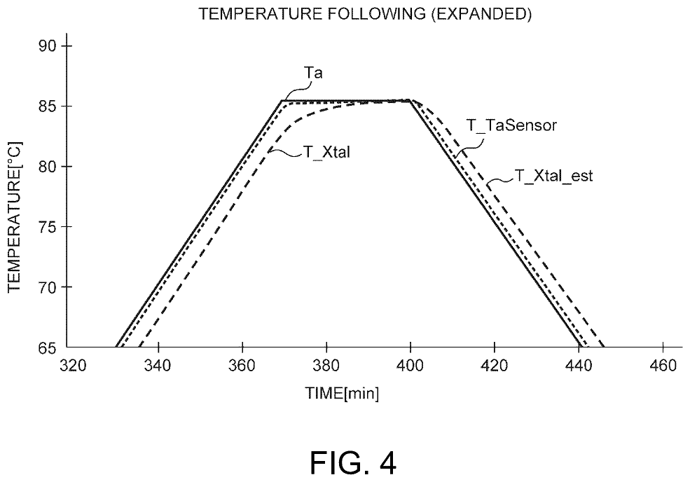

Temperature following characteristics of the present oscillator will be described with reference to FIG. 4.

FIG. 4 is a graph illustrating temperature following characteristics of the present oscillator. FIG. 4 is a graph in which the ambient temperature is increased until after 360 minutes and kept constant, and then decreased from 400 minutes.

As illustrated in FIG. 4, in the temperature following characteristics of the present oscillator, the temperature (T_Xtal) of the crystal vibration plate (reference crystal oscillator 11) rises and falls with a delay with respect to the rise and fall of the ambient temperature (Ta), but the rise and fall of the temperature (T_TaSensor) of the ambient temperature measuring sensor 15 follows the rise and fall of the ambient temperature (Ta) at a position closer to the ambient temperature (Ta) than the crystal vibration plate temperature (T_Xtal).

In the transient thermal response calculation unit 13b, a control value is calculated such that the crystal vibration plate estimated temperature (T_Xtal_est) is the same as the crystal vibration plate temperature (T_Xtal), and the control value is provided to the DDS 14a in the FPGA 14, so that the frequency correction value calculation unit 13a is capable of calculating the frequency correction value using the crystal vibration plate estimated temperature (T_Xtal_est), and the frequency temperature characteristics of the reference crystal oscillator 11 are corrected by the DDS 14a.

According to the present oscillator, the oscillator is a surface-mount type having a metal cover 2, in which an ambient temperature measuring sensor 15 that measures a temperature for correcting frequency temperature characteristics is provided on a substrate 1 on which a plurality of circuits are mounted, the ambient temperature measuring sensor 15 is disposed closer to the metal cover 2 than a reference crystal oscillator 11 including a crystal vibration plate and other circuits, and measures a temperature via a copper foil 16 for thermal conduction soldered to the metal cover 2 by the soldering portion 17, and the measured temperature is used for correcting the frequency temperature characteristics, thereby producing an effect of preventing a delay in correction of frequency temperature characteristics by measuring an ambient temperature before a temperature of the crystal vibration plate changes and reducing hysteresis of the frequency temperature characteristics.

In addition, according to the present oscillator, the temperature value of the transient thermal response corresponding to the temperature change in the reference crystal oscillator 11 is calculated by the transient thermal response calculation unit 13b, the frequency correction value calculation unit 13a calculates the frequency correction value based on the temperature value, and outputs the frequency correction value to the DDS 14a in the FPGA 14, and the DDS 14a corrects the frequency temperature characteristics based on the reference frequency from the reference crystal oscillator 11, so that the transient thermal response calculation unit 13b is capable of calculating the estimated temperature close to the temperature change of the crystal vibration plate of the reference crystal oscillator 11, and the frequency correction value calculation unit 13a is capable of calculating the frequency correction value at the estimated temperature. Therefore, there is an effect of preventing the delay in correction of the frequency temperature characteristics and reducing the hysteresis of the frequency temperature characteristics.

### INDUSTRIAL APPLICABILITY

The present invention is suitable for an oscillator that is capable of preventing a delay in correction of frequency temperature characteristics by measuring an ambient temperature before a temperature of a crystal vibration plate is changed and that is capable of reducing hysteresis of the frequency temperature characteristics.

What is claimed is:

1. A surface-mount type oscillator having a metal cover, the oscillator comprising:
a temperature sensor disposed on a substrate, on which a plurality of circuits are mounted, at a position where a distance to the metal cover is shorter than a distance to the plurality of circuits and configured to measure a temperature via a copper foil for thermal conduction soldered to the metal cover in order to correct frequency temperature characteristics of a crystal vibration plate;
a transient thermal response calculation unit with respect to a structural transient thermal response, calculate, as a crystal vibration plate estimated temperature (T_Xtal_est), a temperature value having a thermal conduction delay that becomes the same as a temperature (T_Xtal) of the crystal vibration plate which is obtained by simulation from a value (T_TaSensor) of a temperature measured by the temperature sensor, a value (T_TaSensor) having a smaller thermal conduction delay than a temperature (T_Xtal) of the crystal vibration plate when the crystal vibration plate receives thermal conduction of an ambient temperature (Ta), and configured to calculate a control value based on the crystal vibration plate estimated temperature (T_Xtal_est); and
a frequency correction value calculation unit configured to compute a correction value of the frequency temperature characteristics based on the control value calculated from the crystal vibration plate estimated temperature.

2. The oscillator according to claim 1,
wherein the transient thermal response calculation unit includes a CR filter-type transient thermal model including parameters of a thermal resistance value and a thermal capacity value of the transient thermal response by simulation, and calculates the crystal vibration plate estimated temperature by using the transient thermal model.

3. The oscillator according to claim 1,
wherein the copper foil for thermal conduction is soldered to the metal cover at corner portions at four corners of the substrate, and the temperature sensor is provided near the corner portion.

4. The oscillator according to claim 1,
wherein the temperature sensor outputs the measured temperature to the transient thermal response calculation unit by a serial communication method of inter-integrated circuit communication.
